(19) United States
(12) Patent Application Publication
(10) Pub. No.: US 2021/0288112 A1
(43) Pub. Date: Sep. 16, 2021

(54) ORGANIC COMPONENT FOR CONVERTING LIGHT INTO ELECTRICAL ENERGY WITH IMPROVED EFFICIENCY AND SERVICE LIFE IN THE CASE OF PARTIAL SHADING

(71) Applicant: Heliatek GmbH, Dresden (DE)

(72) Inventors: Bruno Heimke, Dresden (DE); Christian Uhrich, Dresden (DE); Martin Pfeiffer, Dresden (DE)

(21) Appl. No.: 16/336,484

(22) PCT Filed: Sep. 26, 2017
(86) PCT No.: PCT/EP2017/074424

§ 371 Date: Mar. 26, 2019

(30) Foreign Application Priority Data
Sep. 26, 2016 (DE) 10 2016 118 177.3

(51) Int. Cl. H01L 27/30; H01L 51/42; H01L 51/44; H01L 51/00

(52) U.S. Cl. CPC H01L 27/301; H01L 51/4273; H01L 2251/303; H01L 51/0009; H01L 51/0037; H01L 51/441

(57) ABSTRACT

The invention relates to organic components for converting light into electrical energy, comprising integrated bypass diodes, which are integrated into the optoelectronic stack, in order to increase the efficiency and the service life of the optoelectronic component in the case of partial shading/shading of individual cells or cell segments. Said components can also be produced for large-area applications in the roll-to-roll method.

### CROSS-REFERENCE TO PRIOR APPLICATIONS

This application is a U.S. National Phase application under 35 U.S.C. § 371 of International Application No. PCT/EP2017/074424, filed on Sep. 26, 2017, and claims benefit to German Patent Application No. DE 10 2016 118 177.3, filed on Sep. 26, 2016. The International Application was published in German on Mar. 29, 2018 as WO 2018/0055214 under PCT Article 21(2).

### FIELD

The invention describes, on the basis of the example of organic solar cells, an arrangement of an optoelectronic module, comprising various cells, which may be partly shaded during use, and which guarantee an improved efficiency and a longer service life of the module despite the shading.

### BACKGROUND

Optoelectronic components, for example solar cells, are produced as modules which are interconnected in series and/or in parallel. Individual modules consist of a plurality of cells generally interconnected in series with one another, often in the form of cell strips.

One problem of the interconnected modules in the case of partial shading of individual modules/cells is that the shaded cells constitute reverse-biased diodes with respect to the unshaded or more weakly shaded cells interconnected in series therewith. They thus impede the flowing away of the photogenerated current, which adversely affects the efficiency. Moreover, there is the risk that in the shaded cells a concentrated current flow through defect sites can occur, which can lead to local overheating and ultimately to irreversible degradation of the cell and thus to a loss of efficiency of the module.

One example of a degradation brought about purposefully is illustrated in FIG. 1. It is clearly discernible that this leads to the visible surface of the module being destroyed at points and is not desirable.

The goal of economically viable production is the production of large-area, efficient modules having a long service life.

From an economic standpoint, a failure of individual cells in the case of large-area modules, having module widths of greater than 50 cm, preferably greater than 1 m, and module lengths of greater than 2 m, preferably greater than 5 or 10 m, is more serious than the failure of small-area cells or modules, of 1 cm×1 cm, for example. A corresponding exchange is cost-intensive for the user and therefore likewise not desirable.

Bypass diodes are used in conventional thin-film photovoltaics. In this case, individual or a plurality of modules are subsequently provided with bypass diodes.

In the field of organic photovoltaic solar cells, EP 1 920 468 B1 proposes equipping a module or a solar cell with a bypass diode arranged alongside, wherein the bypass diode and the solar cells differ in terms of construction, primarily in terms of construction of the transport layers. The associated original international application WO 2007 028 036 A2 furthermore discloses a dye-sensitized solar cell in which fluorinated tin oxide is used between an electrode and the photoactive layer. One disadvantage of this arrangement is that this can only be used for dye-sensitized solar cells.

WO 2007 028 036 A2 furthermore discloses the necessary use of two layers 160 (top cover) and 170 (bottom cover), which are applied on the electrodes in the region of the bypass diode in order that the bypass diode does not generate current when the photovoltaic cells are illuminated.

US 2015 0349164 A1 discloses an integrated bypass diode in a solar cell, wherein the bypass diode and the solar cell comprise different regions alongside one another on the substrate and are completely electrically isolated by trenches, and the contacting is only effected subsequently.

### SUMMARY

In an embodiment, the present invention provides an organic component for converting light into electrical energy, comprising at least one module, at least one bottom contact in proximity to a substrate, and at least one top contact, wherein each module comprises at least two organic optoelectronic cells and at least one integrated bypass diode, wherein a) the optoelectronic cells comprise an organic optoelectronic stacked layer system arranged between the bottom contact and the top contact, and the optoelectronic cells are connected in series, b) the integrated bypass diode is arranged with the optoelectronic cells on a substrate such that each bypass diode is interconnected in parallel with exactly one or with a plurality of optoelectronic cells, and the integrated bypass diode without contacts is arranged such that it has the same reverse direction between the bottom contact and the top contact as strips of the optoelectronic cells, and the bypass diode is integrated in such a way by structuring, alongside the strips of the optoelectronic cells on the substrate, and c) characterized in that the bottom contact of a strip of the optoelectronic cells is electronically connected to the top contact of an assigned bypass diode and the bottom contact of the assigned bypass diode is electronically connected to the bottom contact of an adjacent strip of optoelectronic cells.

In another embodiment, the invention provides an organic component for converting light into electrical energy, comprising at least one module, at least one bottom contact in proximity to a substrate, and at least one top contact, wherein each module comprises at least two organic optoelectronic cells and at least one integrated bypass diode, wherein a) the optoelectronic cells comprise an organic optoelectronic layer system arranged between the bottom contact and a rear contact, and the optoelectronic cells are connected in series, b) the integrated bypass diode is arranged with the optoelectronic cells on a substrate such that each bypass diode is interconnected in parallel with exactly one or with a plurality of optoelectronic cells, and the integrated bypass diode has a reverse direction between the contacts that is opposite to that of the optoelectronic cells, and the bypass diode is integrated in such a way by structuring, alongside the strips of the optoelectronic cells on the substrate, and c) characterized in that the top contact of the bypass diode is electrically connected to the top contact of the assigned strip of optoelectronic cells and the bottom contact of the bypass diode is electrically connected to the bottom contact of the assigned strip of the optoelectronic cells.

In yet another embodiment, the invention provides an organic component for converting light into electrical energy, comprising at least one module, at least one bottom contact in proximity to a substrate, and at least one top contact, wherein each module comprises at least two organic optoelectronic cells and at least one integrated bypass diode, wherein a) the optoelectronic cells comprise an organic optoelectronic layer system arranged between the bottom contact and a rear contact, and the optoelectronic cells are connected in series, b) the integrated bypass diodes are arranged with the optoelectronic cells on a substrate such that each bypass diode is interconnected in parallel with exactly one or with a plurality of optoelectronic cells, wherein c) the integrated bypass diodes without contacts and the optoelectronic layer stack are arranged in a manner stacked one above another between a common bottom contact and a common top contact, wherein i) the layer sequence of the integrated bypass diode without contacts is applied on the bottom contact, ii) the optoelectronic layer stack is applied between the bottom contact and the top contact or is applied between the bypass diodes without contacts, applied on the bottom contact, and the top contact, and iii) the region of the bypass diode and the optoelectronic layer stack is interrupted by a structuring process such that the layer system of the integrated bypass diode without contacts is electrically connected to the top contact.

In still yet another embodiment, the present invention provides a method for producing organic solar cells with integrated bypass diodes, comprising the following steps of a) providing a substrate, b) applying a bottom electrode and structuring the bottom electrode, c) applying a layer stack of the integrated bypass diode and a layer stack of the optoelectronic cells without their rear contacts with structuring, after applying individual or a plurality of layers of the bypass diode and/or the layer stack of the optoelectronic cells; and d) applying the rear contact including its structuring.

### BRIEF DESCRIPTION OF THE DRAWINGS

The present invention will be described in even greater detail below based on the exemplary figures. The invention is not limited to the exemplary embodiments. Other features and advantages of various embodiments of the present invention will become apparent by reading the following detailed description with reference to the attached figures which illustrate the following:

FIG. 1 shows a photograph for illustrating the problem of shaded cells or cell regions in the case of cell degradation caused deliberately.

FIG. 2a and FIG. 2b show the arrangement according to the invention in which the integrated bypass diode and the layer sequence of a cell are arranged as a stack between bottom contact and top contact (sandwich arrangement).

FIG. 3 illustrates the possible forms of the integrated bypass diode applied directly on the bottom contact, in accordance with a sandwich arrangement, cf. FIG. 2.

FIG. 4 shows the embodiment according to the invention of the integrated bypass diode, which are arranged alongside the photovoltaic stack.

FIG. 5 illustrates the laser structuring for producing the integrated bypass diode.

FIG. 6 and FIG. 7 show the current-voltage characteristic curve and a thermographic photograph for the example shown in FIG. 4.

FIG. 9 shows the current-voltage characteristic curve for the example in accordance with the structuring shown in FIG. 9.

FIG. 10 and FIG. 11 show the current-voltage characteristic curves of printed integrated bypass diodes for use in solar cells with a sandwich arrangement.

FIG. 12 shows the current-voltage characteristic curve of a single-carrier device as integrated bypass diode for use in organic optoelectronic components in a sandwich arrangement.

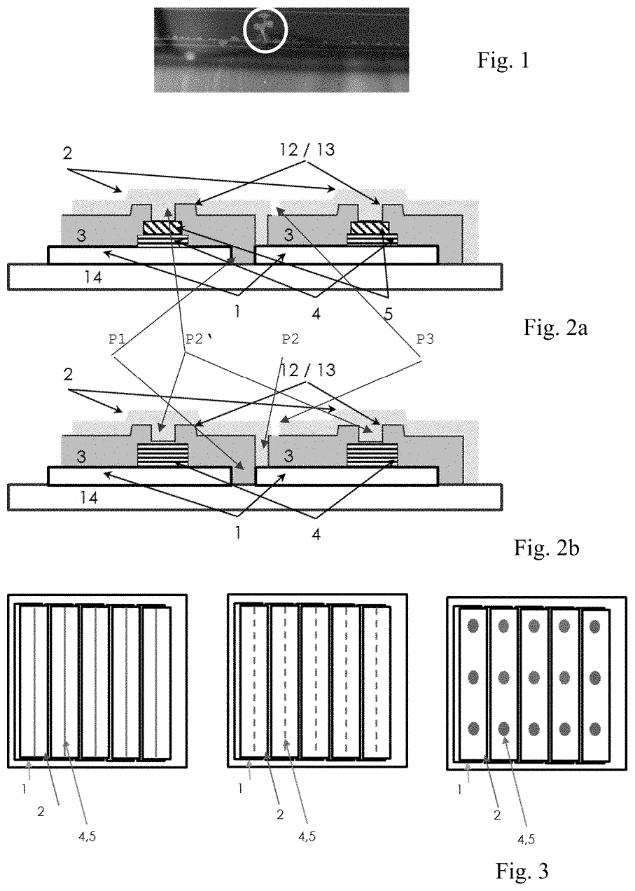

### DETAILED DESCRIPTION OF THE INVENTION

In accordance with an aspect of the invention, the invention provides an arrangement of an optoelectronic component, preferably of a solar cell, comprising at least one module, having a better efficiency in the case of (partial) shading of individual cells or cell regions and an increase in the service life of partly and/or fully shaded cells or cell strips, and to reduce the disadvantages described in the prior art.

In solving the problem, what is furthermore demanded is that the proposed solution for improving the efficiency and the service life in the case of partial shading adversely affects the optical surface of the solar cell (modules) as little as possible for a user and the production of the inventive components can be integrated in a roll-to-roll process and is also suitable for large-area optoelectronic modules.

A further problem addressed is that of specifying a production method for the arrangement according to the invention, wherein said method is preferably able to be integrated in a roll-to-roll process.

### Definition of Terms

An optoelectronic component consists of at least one module having photoactive layers. An organic optoelectronic component is an optoelectronic component having at least one organic photoactive layer. The latter consists of at least one module. A module consists of various (photoactive) cells, which are particularly preferably interconnected in series, but a parallel interconnection is also possible. A strip or cell strip is a specific arrangement of the cells in a module, wherein a cell exhibits its elongate extent over the module width. According to the invention, part of a strip is understood to mean a partial region of a strip that is delimited by at least one bypass diode or contains a bypass diode if bypass diodes are arranged on a strip. The inventors understand an “integrated bypass diode” to be a component having a voltage blocking-state region and a conducting-state region, wherein the integrated bypass diode according to the invention brings about a low current flow at the VMPP of the corresponding optoelectronic cell of the optoelectronic component and a high current flow in the case of reverse loading of the corresponding optoelectronic cell of the optoelectronic component. The term “integrated bypass diode” hereinafter is understood to mean all variations according to the invention if they fulfill the required objective, even if they do not denote a traditional diode.

Organic optoelectronic cells differ in single, tandem or multiple cells depending on the number of photoactive layer systems arranged by transport and further layers in the layer structure between the two bottom and top contacts. Tandem and multiple cells consist of at least two subcells arranged one above another between the electrodes, wherein each subcell comprises at least one photoactive layer system comprising at least one photoactive (light-absorbing) layer and at least one transport layer.

Within the meaning of the present invention, small molecules are understood to mean non-polymeric organic molecules having monodisperse molar masses of between 100 and 2000 g/mol which are present in the solid phase at standard pressure (air pressure of the atmosphere surrounding us) and at room temperature. In particular, said small molecules can also be photoactive, wherein photoactive is understood to mean that the molecules change their charge state under incidence of light.

### DISCLOSURE OF THE INVENTION AND TECHNICAL EFFECT OF THE INVENTION

The problem is solved by means of an arrangement of an optoelectronic component, of a solar cell, in which at least one bypass diode is integrated. The integrated bypass diode can be printed or vapor-deposited.

In a first embodiment, at least one integrated bypass diode and the layers of the organic component of a cell are arranged one above another between the electrodes, wherein the layers of the organic component are at least partly interrupted or bridged in the region of the bypass diode, such that there is a direct electrical contact of the layers of the bypass diode with bottom and top contacts. This arrangement is referred to hereinafter as sandwich arrangement.

In an alternative embodiment, the integrated bypass diode and the organic optoelectronic cells are arranged alongside one another on the substrate and are produced and suitably interconnected by means of targeted structuring, preferably laser structuring, during production; this arrangement is referred to hereinafter as a laser-processed arrangement. In order to achieve better results for the integrated bypass diodes thus produced, a treatment of the applied layers in the region of the integrated bypass diode is necessary in order that, on account of their interconnection with the organic optoelectronic cells, said layers do not reduce the efficiency of the optoelectronic cells so much during operation.

The structuring can be fashioned such that the bypass diode is integrated alongside the strips of the optoelectronic cells or into the strips of the optoelectronic cells on the substrate in such a way that the bottom contact of a strip of the optoelectronic cells is electronically connected to the top contact of the assigned bypass diode and the bottom contact of the assigned bypass diode is electronically connected to the bottom contact of the adjacent strip of optoelectronic cells. In this case, the bypass diode should have the same reverse direction between the bottom and top contacts as the strips of the optoelectronic cells.

In terms of process engineering, the simplest procedure in this case is to use the same layer stack for the bypass diode and the optoelectronic cells. Furthermore, this approach has the advantage that a very homogeneous optical impression arises since the area of the bypass diodes does not differ from the optoelectronic cells in terms of color. However, this variant has the disadvantage that the bypass diode is likewise photoactive and thus generates a current in the opposite direction to the optoelectronic component. This disadvantage can be accepted if the area of the bypass diode is small (less than 10%, but preferably less than 5% or with further preference less than 2%, very particularly preferably less than 0.5%, of the area of the assigned strip). The proportion of the area required for bypass diodes can also be minimized according to the invention by the bypass diodes being made very narrow (less than 8 mm, preferably less than 5 mm, with further preference less than 2 mm). This necessitates integrating overall more bypass diodes into a specific total area, but is nevertheless advantageous since the evolution of heat of many small bypass diodes can be dissipated more easily than for fewer but larger bypass diodes. In this case, the optimum dimensioning of the bypass diodes depends sensitively on the accuracy of the structuring method.

The losses mentioned can be reduced according to the invention by targeted reduction of the photovoltaic function (external quantum efficiency of the charge carrier generation) of the layer stack of the optoelectronic component in the region of the bypass diode by means of suitable aftertreatment (e.g. by means of laser radiation, UV radiation, electron or ion bombardment). If the optoelectronic component is a multiple cell (tandem, triple or quadruple cell), according to the invention it suffices here to effect targeted reduction of the quantum efficiency of at least one subcell in the region of the bypass diode.

A reduction of the relative area requirement of the bypass diodes requires the highest possible loading capacity of the bypass diode with a current flow in the forward direction. In the case of multiple cells as optoelectronic component, said loading capacity can also be increased according to the invention by one or more subcells of the multiple cell being removed in the region of the bypass diode by means of suitable ablation methods and thus the same current flow being attained at lower voltage, which corresponds to a lower evolution of heat.

For further minimization of the losses, it can be expedient, within the same interconnection scenario, i.e. likewise with the same reverse direction between bottom contact and top contact of the optoelectronic component, in the region of the bypass diode, to deposit a different layer stack, which is preferably not photoactive or is at least less photoactive and is optimized for maximum current-carrying capacity. Maximum current-carrying capacity here requires the use of materials that are as thermally stable as possible, i.e. high charge carrier mobilities in the region of the depletion zone of the diode (intrinsically or lightly doped) and an as barrier-free injection as possible of at least one charge carrier type under applied forward voltage. According to the invention, particular preference is given to components with bipolar injection into the depletion zone under applied forward voltage, in the case of which the injected charge carrier clouds mutually permeate one another, which reduces the space charge limitation of the current flow. With the use of organic materials in the depletion zone of the bypass diode, a bipolar injection can be made possible according to the invention by the use of a mixed layer composed of a hole-conducting and an electron-conducting material, which form an interpenetrating, bicontinuous network. Furthermore, it is advantageous to use doped layers and in this case to choose the doping profile or the doping density such that the thickness of the depletion zone is just precisely what is necessary for a sufficiently good blocking behavior, typically approximately 15 to 50 nm for organic semiconductors.

Alternatively, if the integrated bypass diode and the layer sequence of the organic optoelectronic cells are arranged alongside one another on the substrate, at least one integrated bypass diode can be applied before the layer sequence of the optoelectronic cells. Printing or vapor deposition of the bypass diode is possible in this case.

If the layer stack of the optoelectronic component is deposited onto the entire area, i.e. also onto the region in which a layer stack for the bypass diode was applied on the bottom contact, this has to be removed again at least partly by means of a suitable ablation method (e.g. laser ablation) in the region of the bypass diode in order to enable an electrical contact of the layer stack of the bypass diode with the top contact. In this case, according to the invention, the layer stack of the bypass diode can comprise a conductive layer, for example a metal or PEDOT:PSS, as the last layer, such that it is not necessary for the entire area of the bypass diode to be exposed by ablation. Rather, it suffices in this case to enable electrical connections between the bypass diode and the top contact in a pointlike or linear fashion by means of ablation.

The structuring of the individual layers of the cells of the optoelectronic component with the bypass diode and/or by themselves can be carried out for example by means of laser ablation, electron or ion beam ablation, shadow masks or the like.

The components according to the invention are produced by means of the suitable choice of the order of the layers to be applied in conjunction with corresponding structurings of the individual or plurality of layers.

By virtue of the order of applying the layers of the bypass diode and of the layer system of the cells of the optoelectronic component, an integration into a roll-to-roll method is possible and the production of large-area modules is likewise possible.

### Advantageous Effect of the Invention

The bypass diode arranged in parallel with one or more organic cells, in the case of (partial) shading, when the current flow in the organic cell decreases, enables a higher current flow in the reverse direction of the organic cell at a given voltage.

The advantage of the integrated bypass diode according to the invention enables a uniform optical view of the surface of the optoelectronic component, and increases the efficiency in the case of shading of individual cells of the component, and, in association therewith, a lengthening of the service life of the complete optoelectronic component. In a further embodiment, it is possible to provide patterns on the surface of the optoelectronic component with the aid of the arrangement of the integrated bypass diode.

In the arrangement according to the invention in which the integrated bypass diode has a stack identical or almost identical to that of the optoelectronic cells arranged alongside the integrated bypass diode, by means of the processing according to the invention, preferably by means of lasers during the production process, and the optional laser treatment of the stack in the region of the integrated bypass diode, it is not necessary to use additional cover layers on the region of the integrated bypass diode in order that the bypass diode does not generate current when the photovoltaic cells are illuminated, as disclosed in WO 2007 028 036 A2. This arrangement according to the invention is thus better suited to a roll-to-roll process.

The production method according to the invention enables production in the roll-to-roll process without extensive adaptations in the production method during the production of the organic optoelectronic component with integrated bypass diode in comparison with the production of the optoelectronic component without a bypass diode.

The module according to the invention of the optoelectronic component (0) comprises at least one integrated bypass diode (4), at least one layer stack of an organic cell (3), at least two contacts, wherein contacts in proximity to a substrate are referred to as bottom contact or bottom electrode (1) and contacts remote from the substrate are referred to as a top contact or top electrode (2).

Hereinafter, in regard to a layer stack of the organic optoelectronic cell or the layer stack of the integrated bypass diode, it is assumed that layer stack is taken to mean the layer system between the electrodes, that is to say that the layer stack without electrical bottom and top contacts is meant.

In one embodiment, the layer stacks of the organic optoelectronic cells are arranged alongside one another as strips with their contacts and are interconnected in series. Each cell strip has its own bottom electrode and top electrode. The series connection is effected by electrically connecting the bottom electrode (1) of one cell to the top electrode (2) of the next cell.

In one embodiment, exactly one integrated bypass diode is assigned to each cell strip of the optoelectronic cells.

In another embodiment, an integrated bypass diode is assigned to each part of a strip of the optoelectronic cells. This makes it possible, primarily in the case of large-area and wide modules, modules wider than 25 cm, preferably wider than 50 cm and particularly preferably wider than 1 m, to assign a plurality of smaller bypass diodes to a strip of the optoelectronic cells. A further advantage is that the integrated bypass diode can thereby be chosen to be small enough and problems, for example thermal problems, in carrying away the current in larger cells in the case of only one bypass diode are avoided.

In a further embodiment, an integrated bypass diode can be assigned to a plurality of optoelectronic cells/cell regions.

In one embodiment, the area proportion of the integrated bypass diode on the bottom contact, i.e. the sum of the area proportion of all the integrated bypass diodes above said bottom contact or in conjunction with said bottom contact, is less than 20%, preferably less than 10%, particularly preferably less than 5%, very particularly preferably less than 1%, of the respective bottom contact area.

In a further embodiment, the area proportion of all the integrated bypass diodes in a module is less than 20%, preferably less than 10%, particularly preferably less than 5%, very particularly preferably less than 1%, of the module area.

The layer stack of an optoelectronic cell, said layer stack being arranged between the bottom contact and the top contact, comprises a plurality of layers. The layer stack can be embodied as a single cell, a tandem cell or a multi-cell, the designation being determined by the number of subcells, wherein each subcell contains at least one photoactive layer, which are separated by transport layers, preferably doped transport layers, particularly preferably by wide-gap layers, and optional recombination layers and can themselves consist of a plurality of layers.

The p- or n-layer systems, also referred to as just p- or n-layer, can consist of a plurality of layers, wherein at least one of the layers of the p- or n-layer system is p-doped or n-doped, preferably as p- or n-doped wide-gap layer. The i-layer system, also referred to as i-layer, is undoped or more lightly, that is to say more weakly, doped compared with the p- and/or n-layers in the subcell and is embodied as a photoactive layer. Each of said n-, p-, layers can consist of further layers, the n- and/or p layer consisting of at least one doped n- and/or p-layer, respectively, the doping of which contributes to an increase in the charge carriers. This means that the layer stack of the optoelectronic cell consists of an expedient combination of p-, n, and i-layer systems, that is to say that each subcell comprises an i-layer system and at least one p- or n-layer system.

One possible construction of the layer stack of the optoelectronic cell is disclosed in WO 2004 083 958 A2, WO 2011 013 219 A1, WO 2011 138 021 A2, WO 2011 161 108 A1.

In the applications cited here, use is preferably made of layer stacks in which the photoactive layers comprise absorber materials which are able to be vapor-deposited and are applied by vapor deposition. For this purpose, use is made of materials belonging to the group of “small molecules”, which are described inter alia in WO 2006 092 134 A1, WO 2010 133 208 A1, WO 2014 206 860 A1, WO 2014 128 278 A1, EP 16 181 348.0, EP 16 181 347.2. The photoactive layers thus form acceptor-donor systems, and can comprise of a plurality of individual layers, or of mixed layers, as a planar heterojunction, and preferably as a bulk heterojunction. The inventors prefer optoelectronic layer stacks which can be applied completely by vapor deposition.

With the corresponding choice of layer stacks, transparent or partly transparent optoelectronic components can also be produced besides opaque components. The inventors understand transparent layers/electrodes to mean those having a transmission of greater than 80%, wherein ideally the other electrode is embodied as at least 50% reflective. The inventors understand a partly transparent or semitransparent layer/electrode to mean a layer/electrode having a transmission of between 10% and 80%. Opaque electrodes are not transparent layers.

In one embodiment device, the top electrode comprises silver or a silver alloy, aluminum or an aluminum alloy, gold or a gold alloy, or a combination of these materials, preferably comprising Ag:Mg or Ag:Ca as silver alloy.

According to the invention, layer stack of the optoelectronic cell is also understood to mean a layer stack of dye solar cells or polymer solar cells.

According to the invention, the layer stack of the optoelectronic cells can also comprise perovskite-based solar cells.

Furthermore, it is possible to insert passivation layers, preferably comprising molybdenum oxide or tungsten oxide, adjoining the electrodes, preferably adjoining the top electrode, in order to reduce a degradation of the organic layer stack as a result of environmental influences.

Furthermore, the finished modules can be provided or encapsulated with additionally applied barrier layers in order to further minimize a degradation as a result of environmental influences.

### Sandwich Arrangement

In one embodiment, the bypass diode can be arranged in a sandwich arrangement with the optoelectronic stack, wherein the integrated bypass diode and the optoelectronic layer stack are arranged one above another between the common bottom contact and the top contact, see FIG. 2.

The integrated bypass diode can be realized by a single layer stack (4), see FIG. 2a), or by at least two separate layer stacks (4, 5), see FIG. 2b).

FIG. 2a) and FIG. 2b) show the optional intermediate layers (12) and/or (13) as an example with respect to the top electrode (2). Said intermediate layers (12, 13) can likewise optionally be arranged with respect to the bottom electrode (1). Preferably, the bypass diode is applied on the electrode near the substrate. At least one further layer (12)/(13) can also be introduced between the electrode near the substrate and the integrated bypass diode and/or else between the integrated bypass diode and the electrode (top contact) remote from the substrate.

Passivation layers for protecting the bypass diode or the layer construction of the optoelectronic cells or injection layers are expedient, inter alia, as further introduced layers. For the contacting of the integrated bypass diode, it is necessary that the layers of the organic component, the layer stack of the optoelectronic cells, which were applied after the bypass diode on the bottom electrode and the bypass diode, are at least partly interrupted or bridged in the region of the integrated bypass diode such that there is a direct electrical contact of the layers of the integrated bypass diode with bottom contact and top contact.

The structuring of the individual layers in order to ensure a direct electrical contact of the integrated bypass diode with the top contact can be carried out for example by means of laser ablation, electron or ion beam ablation, shadow masks or other known methods familiar to the person skilled in the art, preferably by means of laser ablation.

The individual cells of the organic optoelectronic module are connected in series. The integrated bypass diode is in parallel with an organic cell. In a further embodiment disposition, the integrated bypass diode can be interconnected in parallel with a plurality of organic cells.

The layer stack of the optoelectronic cells (optoelectronic layer stacks) is preferably embodied as an organic layer stack, wherein the layer stack contains at least one photoactive layer system, preferably an organic photoactive layer system, and is thus embodied as a single, tandem or multiple cell.

Preferably, the layer stack of the optoelectronic cells contains small molecules that can be vapor-deposited. The individual subcells in the optoelectronic cells comprise at least one doped transport layer besides at least one photoactive (light-absorbing) layer. In individual further embodiment dispositions, the optoelectronic layer stack can comprise even further doped, partly doped or undoped layers, for example passivation and cavity layers, such that each subcell constitutes an in-, ip-, pin-, nip-, pnip-, etc. cell, wherein each of the individual i-, n-, p-layers can be represented by a plurality of layers. The subcells can be separated by recombination layers.

In one embodiment according to the invention, the bypass diodes are in the form of various discrete shapes, for example round, angular, rectangular, solid or interrupted lines. The production of the various discrete shapes, preferably only one discrete shape being used in a module, are simple to integrate into the roll-to-roll production process. FIG. 3 shows the possible plan views depending on the discrete shape used for the integrated bypass diode, for the components according to the invention as shown in FIG. 2.

In a further embodiment, it is proposed that, according to the invention, the layer stack of the bypass diode comprises a conductive layer, for example a metal or PEDOT:PSS, as the last layer, such that it is not necessary for the entire area of the bypass diode to be exposed by ablation. Rather, it suffices in this case to enable electrical connections between the bypass diode and the top contact in a pointlike or linear fashion by means of ablation.

In one preferred embodiment, the bottom contact of the solar cell forms a cathode, and the top contact an anode.

According to the invention, in one embodiment, it is proposed that the top electrode, as anode, predominantly or completely comprises a metal having a thermal work function of less than 4.5 eV, for example aluminum or an aluminum alloy, silver or a silver alloy, the latter preferably as Ag:Mg or Ag:Ca.

In this case, it is further proposed that the integrated bypass diode comprises at least one of the following layers or layer sequences:
a. an inorganic or organic, preferably intrinsic or weakly doped layer, wherein the concentration of the dopants, in the case of weak doping of the layer, in said layer is less than 10%, preferably less than 5% and particularly preferably less than 1%, wherein said layer is embodied as a hole-conducting layer;
b. a non-intrinsic organic or inorganic layer, i.e. p- or n-doped layer, having a work function of greater than 4.5 eV, followed by an insulating layer for forming a tunnel diode with respect to the anode;
c. a layer comprising a highly doped organic p-type conductor, for example PEDOT:PSS, which, as a result of the oxidants contained therein, incipiently oxidizes the surface of the cathode, and thus leads to the formation of an insulation layer at the interface with the anode, for example composed of metal oxide, metal-sulfur compound or metal-acceptor complexes.

According to the invention, in a further embodiment, it is proposed that the top electrode, as anode, predominantly or completely comprising a metal or a material having an arbitrary thermal work function or wherein a layer comprising a degenerate or highly doped n-type conductor having a thermal work function of less than approximately 4.5 eV is arranged in the region of the integrated bypass diode below the top contact and the bypass diode comprises at least one of the following layers or layer sequences:
a. an inorganic or organic layer, preferably intrinsically or weakly doped, wherein the concentration of the dopants in the layer is less than 10%, preferably less than 5% and particularly preferably less than 1%, wherein the layer is applied on the bottom contact, or
b. a non-intrinsic layer having a work function of greater than 4.5 eV followed by an insulating layer for forming a tunnel diode with respect to the degenerate or highly doped n-type conductor layer.

Furthermore, it is proposed that the thermal work function of the bottom electrode (cathode) in a further embodiment is increased by means of suitable intermediate layers, for example molybdenum oxide, tungsten oxide, PEDOT:PSS, suitable self-assembly monolayer, and/or by means of suitable pretreatment, for example UV-ozone treatment or oxygen plasma treatment, to a value of greater than 4.5 eV, preferably greater than 5.0 eV.

According to the invention, the hole-conducting layer of the integrated bypass diode comprises at least one of the following materials or material classes:
a. low molecular weight, hole-conducting substance having a conjugated pi electrode system and optionally compounds having a conjugated or nonconjugated side chain having a moderate work function of between approximately 4.8 eV and approximately 5.8 eV, particularly preferably between approximately 5.0 eV and approximately 5.5 eV;
b. further preference is given to substances which have correspondingly functionalized side groups or contain a second material which can react with the actual hole-conducting substance by way of correspondingly functionalized side groups, which can be polymerized thermally or under the action of light, preferably UV light, after deposition, for example. Such functional groups are for example vinyl, methacrylates, trichlorosilane, azides, epoxides or oxetanes. Azides are converted into nitrenes by means of UV rays, said nitrenes then bringing about the crosslinking. In the case of the oxetanes, the crosslinking is effected by way of a cationic ring opening polymerization;
c. polymeric hole-conducting compound, preference is given here to compounds having a moderate work function of between approximately 4.8 eV and approximately 5.8 eV, preferably between approximately 5.0 eV and approximately 5.5 eV, and/or compounds having suitable non-conjugated side chains which ensure a sufficient solubility for a printing process; preference is given to substances which have correspondingly functionalized side groups such that after deposition they can be crosslinked thermally or under the action of light, preferably UV light, for example polythiophene, such as PEDOT, conductive colorants, for example Plexcore, polypyrroles, polyamines, such as polyaniline, polyparaphenylene, polyphenylene vinylene, polyphenylene ethynylene, polyvinyl carbazole, polymers containing triarylamine, fluorene or carbazole groups; or
d. a mixture of polymeric, conjugated or non-conjugated substances, for example as binder for facilitating the printing process and/or the layer formation, and a low molecular weight hole-conducting substance; preference is given here to compounds having a moderate work function of between approximately 4.8 eV and approximately 5.8 eV, preferably between approximately 5.0 eV and approximately 5.5 eV, and compounds having suitable non-conjugated side chains which ensure a sufficient solubility for a printing process.

According to the invention, the electron-conducting layer of the integrated bypass diodes comprises at least one of the following materials or material classes:
a. low molecular weight, electron-conducting substance, such as fullerene, or compounds comprising dicarboxylic anhydride, dicarboxylic imide or cyano groups, in particular dicyanovinyl groups, or
b. low molecular weight, electron-conducting substance having a moderate electron affinity of between approximately 3.5 eV and approximately 4.5 eV, preferably between approximately 3.8 eV and approximately 4.5 eV, and compounds having suitable non-conjugated side chains which ensure a sufficient solubility for a printing process, preferably bisimide dyes of naphthalene, anthracene, 2,8-diazaperylene-1,3,7,9-tetraone, perylene, terylene and quarterylene having solubility-mediating alkyl, alkoxy, oligoether and partly fluorinated alkyl groups.

In this case, the core structure of the bisimides either can be unsubstituted or can have electron-withdrawing substituents (F, Cl, CN). This likewise includes bay-linked dimers, trimers and oligomers of perylene bisimide. Decacyclene triimides having the solubility-mediating groups mentioned complete this substance class.

Further low molecular weight, electron-conducting compounds are boron subphthalocyanines, phthalocyanines, polycyclic aromatic and heteroaromatic hydrocarbons having electron-withdrawing substituents (F, Cl, CN), which likewise carry solubility-mediating alkyl, alkoxy, oligoether and partly fluorinated alkyl groups. This likewise includes fluoranthene-fused imides having solubility-mediating groups.

Tetraazabenzodifluoranthene diimides and diketopyrrolopyrrole (DPP)-functionalized acceptors having the abovementioned solubility-mediating groups also form low molecular weight, electron-conducting compounds.

9,9′-Bifluorenylidenes, wherein as a result of electron acceptance the steric hindrance is reduced owing to the 14-π-electron rule being satisfied;
a. truxenone derivatives and dicyanovinylenes and cyanocarboxy-vinylenes derived therefrom; or
b. calamitically shaped molecules having an electron-rich central group, such as fluorene, dibenzosilole, indacenodithiophene and indacenodithieno[3,2-b]thiophene, flanked by electron-poor terminal acceptors, such as rhodanines, imides, indandiones, dicyanovinylenes, which are often bonded thereto via vinyl bridges;
c. polymeric electron-conducting substance, for example cyano-substituted polyphenylene vinylene; preference is given here to compounds having a moderate electron affinity of between approximately 3.5 eV and approximately 4.5 eV, preferably between approximately 3.8 eV and approximately 4.5 eV, and compounds having suitable non-conjugated side chains which ensure a sufficient solubility for a printing process, for example poly((9,9-dioctylfluorene)-2,7-diyl-alt-[4,7-bis(3-hexylthiophen-5-yl)-2,1,3-benzothiadiazole]-2′,2″-diyl) (F8TBT) and polymers composed of spirobifluorene and diketopyrrolopyrrole units and polymers having cyano-substituted vinyl units;
d. mixture of a polymeric, conjugated or non-conjugated substance, such as binder for facilitating the printing process and/or the layer formation, and a low molecular weight electron-conducting substance; preference is given here to compounds having a moderate work function of between approximately 3.5 eV and approximately 4.5 eV, preferably between approximately 3.8 eV and approximately 4.5 eV, and compounds having suitable non-conjugated side chains which ensure a sufficient solubility for a printing process.

In a further embodiment, the integrated bypass diode can be an organic, bipolar conductive layer, comprising a mixture of preferably one of the electron-conducting materials mentioned above and a hole-conducting material mentioned above.

Alternatively, the integrated bypass diode can comprise materials which are preferably vapor-deposited in vacuo or applied from solution or in a printing process before the layer system of the optoelectronic cells onto the bottom electrode or onto the pretreated bottom electrode.

Furthermore, according to the invention, a further embodiment of the integrated bypass diode is disclosed for use in optoelectronic devices, preferably in photovoltaic devices. The integrated bypass diode is constructed analogously to the above integrated bypass diodes or alternatively in the form of a single-carrier device.

The inventors have furthermore surprisingly established that the same effect of an integrated bypass diode is achieved with the use of a layer stack as “integrated bypass diode” between two electrodes in the form of a single-carrier device, comprising three layers of one charge carrier type with an intrinsic layer having a low energetic barrier in the center and two more highly hole- or electron-conducting layers for producing a blocking-state region. The inventors understand a low energetic barrier to be a barrier having a strength of 0.2 to 0.5 eV, preferably to 0.75 eV. The thickness of the intrinsic layer is preferably less than 100 nm, preferably less than 50 nm, particularly preferably less than 20 nm, especially preferably less than 10 nm, very particularly preferably approximately 5 nm.

The same effect is likewise achieved with the use of a layer stack between the two electrodes as “integrated bypass diode” in the form of a single-carrier device, comprising three layers of one charge carrier type, with a weakly doped (intrinsic) layer having a higher energetic barrier in the center and two more highly doped layers for producing a blocking-state region. According to the invention, a higher energetic barrier is understood to mean a barrier of approximately 0.5 to 1.0, preferably to 1.5 eV.

The weakly doped intrinsic layer preferably has a thickness of less than 100 nm, preferably less than 50 nm, particularly preferably less than 20 nm, especially preferably less than 10 nm, very particularly preferably of approximately 5 nm. In the case of a weakly doped layer, the doping is in a range of less than approximately 1 mol %, preferably less than 0.5 mol %, particularly preferably less than 0.1, very particularly preferably less than 0.05 mol %, very particularly preferably approximately 0.01 mol %.

In low voltage ranges (1 to 3 V) only low currents flow through the component since the charge carrier flow is impeded by the energetic barrier. The barrier can be overcome at higher voltages, such that one charge carrier type can flow through the component.

This alternative layer stack can thus be constructed as:

a. p-HTL1/i-HTL2/p-HTL3, (HTL=hole-conducting layer)

b. n-ETL1/i-ETL2/n-ETL3, (ETL=electron-conducting layer)

In cases i) and ii) the result is approximately symmetrical characteristic curves with conducting-state regions for negative and positive voltage ranges in the case of identical materials for HTL1 and HTL3 or for ETL1 and ETL3.

By way of example, CBP (4,4′-bis(N-carbazolyl)-1,1′-biphenyl), TCTA (tris(4-carbazoyl-9-ylphenyl)amine), AZO, or the hole-conducting or electron-conducting materials mentioned above can be used as materials for the layers in the single-carrier device. By way of example, F4-TCNQ can be used for the necessary doping. All other dopants known for the doping of transport layers in organic solar cells can also be used.

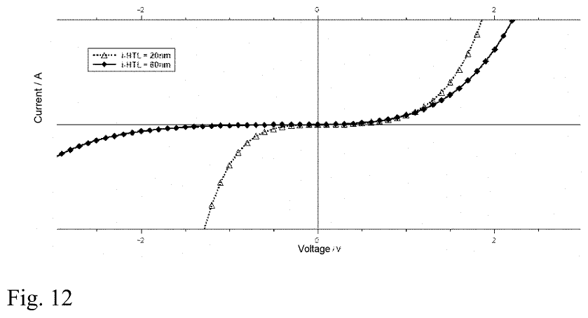

The single-carrier device can furthermore be embodied as MoOx/i-HTL/MoOx, in FIG. 12 by way of example as MoOx/ATO/MoOx. In this case, the first MoOx layer or the last MoOx layer can be embodied as part of the bottom contact (1), of the top contact (2) or as part of the intermediate layers (12, 13).

### Production of the Sandwich Arrangement

After providing a substrate, on the latter the bottom electrode of each cell is applied and structured (P1). This is followed by applying the layer stack(s) of the integrated bypass diodes without electrodes on the bottom contacts, wherein the bypass diodes do not cover the complete area of the bottom contact.

The area proportion of the integrated bypass diode on the bottom contact, i.e. the sum of the area proportion of all integrated bypass diodes above said bottom contact or in conjunction with said bottom contact, is less than 20%, preferably less than 10%, particularly preferably less than 5%, very particularly preferably less than 1%, of the respective bottom contact area.

The area proportion of all integrated bypass diodes in a module is less than 20%, preferably less than 10%, particularly preferably less than 5%, very particularly preferably less than 1%, of the module area.

Applying the bypass diodes can be carried out by means of printing the individual layers, preferably by means of an inkjet, screen printing, gravure printing or flexographic printing process, or by means of vapor deposition of the layer stack, or a combination of printing and vapor deposition, preferably using materials mentioned above, particularly preferably using organic materials or inks comprising organic materials. The use of AZO, for example, can be shown successfully.

According to the invention, this is followed by applying the layer stack of the optoelectronic cells, as a single, tandem or multiple cell, preferably by vapor deposition of small molecules. This is followed by the structuring of the layer stack of the optoelectronic cells (P2) and preferably at the same time the structuring/exposure (P2′) for contacting the integrated bypass diode (4) with the top contact (2).

This is followed by applying the top contact and final structuring (P3).

The structurings can be carried out by means of shadow masks, structured printing methods or laser ablation; the laser ablation is preferably carried out using ultrashort pulse lasers having pulse lengths in the nano-, pico- or femtoseconds range.

In the case of laser ablation for structuring the layer stack of the optoelectronic cells (P2) and the structuring/exposure of the integrated bypass diode (P2′), the process parameters (intensity, overlap, profiles) should be adapted for the P2′ structuring.

Afterward, the module can also be encapsulated in order to protect the layer construction against external influences.

Furthermore, it is possible to apply for example passivation layers for protecting the organic layers of the optoelectronic layer system and/or for protecting the bypass diode during the production process.

### Laser-Integrated Bypass Diode

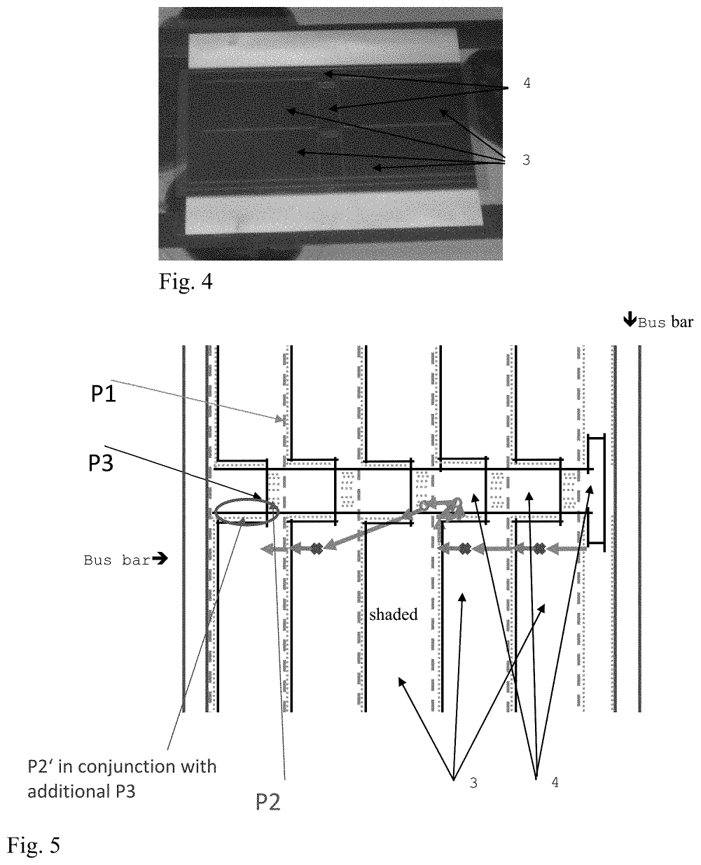

A further embodiment arrangement proposes arranging at least one integrated bypass diode alongside the optoelectronic cells on the substrate between top contact and bottom contact, cf. FIG. 4 and FIG. 5 are produced and suitably interconnected by means of targeted structuring during production.

The invention proposes that at least one integrated bypass diode is assigned to a cell strip.

Furthermore, it is possible for an integrated bypass diode to bridge a plurality of cell strips.

In all cases, the integrated bypass diode is electrically connected in parallel with the cell strips and the cells, represented by cell strips, are connected in series for cell strips extending parallel.

According to the invention, the structuring will be fashioned such that the integrated bypass diode is integrated alongside the strips of the optoelectronic cells or into the strips of the optoelectronic cells on the substrate in such a way that the bottom contact of a strip of the optoelectronic cells is electronically connected to the top contact of the assigned bypass diode and the bottom contact of the assigned bypass diode is electronically connected to the bottom contact of the adjacent strip of optoelectronic cells. In this case, the bypass diode should have the same reverse direction between the bottom and top contacts as the strips of the optoelectronic cells.

In terms of process engineering, the simplest procedure in this case is to use the same layer stack for the bypass diode and the optoelectronic cells. Furthermore, this approach has the advantage that a very homogeneous optical impression arises since the area of the bypass diodes does not differ from the optoelectronic cells in terms of color. However, this variant has the disadvantage that the bypass diode is likewise photoactive and thus generates a current in the opposite direction to the optoelectronic component.

This disadvantage can be accepted if the area of the bypass diode is small, that is to say less than 10%, preferably less than 5% or with further preference less than 0.5% to 2%, of the area of the assigned strip. The proportion of the area required for bypass diodes can also be minimized according to the invention by the bypass diodes being made very narrow, i.e. the width of the integrated bypass diodes is less than 8 mm, preferably less than 5 mm, with further preference less than 2 mm. This necessitates integrating overall more bypass diodes into a specific total area, but is nevertheless advantageous since the evolution of heat of many small bypass diodes can be dissipated more easily than for fewer but larger bypass diodes. In this case, the optimum dimensioning of the bypass diodes depends sensitively on the accuracy of the structuring method.

The losses mentioned can be further reduced according to the invention by targeted reduction of the photovoltaic function, i.e. external quantum efficiency of the charge carrier generation, of the layer stack of the optoelectronic component in the region of the bypass diode by means of suitable aftertreatment, for example by means of laser radiation, UV radiation, electron or ion bombardment. If the optoelectronic component is a multiple cell (tandem, triple or quadruple cell), according to the invention it suffices here to effect targeted reduction of the quantum efficiency of at least one subcell in the region of the bypass diode.

A reduction of the relative area requirement of the bypass diodes requires the highest possible loading capacity of the bypass diode with a current flow in the forward direction. In the case of multiple cells as optoelectronic component, said loading capacity can also be increased according to the invention by one or more subcells of the multiple cell being removed in the region of the bypass diode by means of suitable ablation methods and thus the same current flow being attained at lower voltage, which corresponds to a lower evolution of heat.

For further minimization of the losses, it can be expedient, within the same interconnection scenario, i.e. likewise with the same reverse direction between bottom contact and top contact of the optoelectronic component, in the region of the bypass diode, to deposit a different layer stack, which is preferably not photoactive or is at least less photoactive and is optimized for maximum current-carrying capacity. Maximum current-carrying capacity here requires the use of materials that are as thermally stable as possible, i.e. high charge carrier mobilities in the region of the depletion zone of the diode (intrinsically or lightly doped) and an as barrier-free injection as possible of at least one charge carrier type under applied forward voltage.

According to the invention, particular preference is given to components with bipolar injection into the depletion zone under applied forward voltage, in the case of which the injected charge carrier clouds mutually permeate one another, which reduces the space charge limitation of the current flow. With the use of organic materials in the depletion zone of the bypass diode, a bipolar injection can be made possible according to the invention by the use of a mixed layer composed of a hole-conducting and an electron-conducting material, which form an interpenetrating, bicontinuous network. Furthermore, it is advantageous to use doped layers and in this case to choose the doping profile or the doping density such that the thickness of the depletion zone is just precisely what is necessary for a sufficiently good blocking behavior, typically approximately 15 to 50 nm for organic semiconductors.

Alternatively, likewise in the embodiment that the integrated bypass diode and the organic cells are arranged alongside one another on the substrate, the at least one integrated bypass diode can be applied before applying the optoelectronic layer stack. In this case, printing or vapor deposition of the bypass diode is possible, preferably in vacuo.

The structuring of the individual layers of the cells of the optoelectronic component with the bypass diode and/or by themselves can be carried out for example by means of laser ablation, electron or ion beam ablation, shadow masks or the like.

The components according to the invention are produced by means of the suitable choice of the order of the layers to be applied in conjunction with corresponding structurings of the individual or plurality of layers.

By virtue of the order of applying the layers of the bypass diode and of the layer system of the cells of the optoelectronic component, an integration into a roll-to-roll method is possible and the production of large-area modules is likewise possible.

Preferably, a layer stack applied by vapor deposition in vacuo is selected as layer stack of the optoelectronic cells.

According to the invention, in order to minimize the series resistance of the integrated bypass diode it is proposed to insert additional structurings, preferably as laser structurings, between the integrated bypass diode and the associated optoelectronic cell.

### EXEMPLARY EMBODIMENTS

### Examples of Sandwich Arrangement

The module according to the invention comprises an integrated bypass diode and a layer stack of an organic cell, which are arranged in a sandwich arrangement between the common bottom contact and the top contact, cf. FIG. 2a) and FIG. 2b). In FIG. 2a), the layer sequence of the integrated bypass diode comprises at least two layers in order to illustrate that a tunnel diode can also be arranged between the electrode and the integrated bypass diode or the integrated bypass diode consists of a plurality of layers.

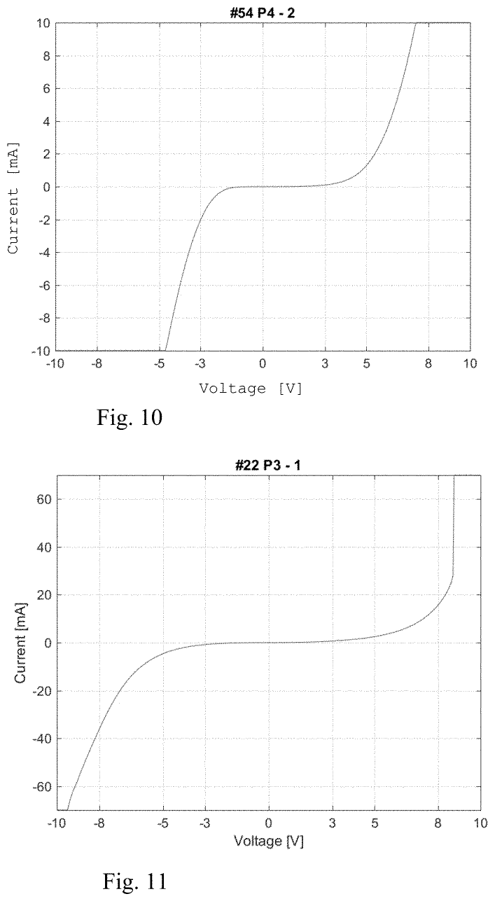

FIG. 10 and FIG. 11 illustrate the current-voltage characteristic curves of two embodiments of such bypass diodes for the sandwich arrangement.
a. FIG. 10 shows the current-voltage characteristic curve of a component having the layer sequence: glass/ITO (130 nm)/ZnO (30 nm)/AZO (60 nm)/rear contact. In order to produce the component a 30 nm thick ZnO layer composed of ZnO nanoparticles was deposited onto an ITO-coated glass substrate by the inkjet method. This was followed by the deposition of an azo layer (60 nm), likewise nanoparticles using the inkjet method. The rear contact was deposited by means of a shadow mask with the aid of vacuum deposition. The ITO is structured in such a way as to yield an active area of approximately 6 mm² as a result of the overlap with the rear contact. The component exhibits a low current flow in the range of −2 to +3 V. In the ranges of voltages of less than −2 V and greater than +3 V, current flows and the characteristic curves show a comparatively steep rise. The component whose characteristic curve is shown in FIG. 10 thus satisfies the requirements that it can be used as integrated bypass diode in an organic optoelectronic component.
b. FIG. 11 shows the current-voltage characteristic curve of a component having the layer sequence: glass-ITO (130 nm)-PTAA (30 nm)-AZO (60 nm)-rear contact. As in example A), the PTAA (poly [bis(4-phenyl)(2,4,6-trimethylphenyl)amine) layer and AZO layer (composed of nanoparticles) were printed using the inkjet method. The rear contact was once again deposited by means of a shadow mask with the aid of vacuum deposition. This component also exhibits a voltage range (−3 to +3 V) with low current flow (blocking-state region). In the voltage ranges of less than −3 V and greater than +3 V, a comparatively high current flows. This component is also suitable for integration as a bypass diode in a sandwich arrangement.

For this purpose, the bypass diode is applied directly on the bottom contact, and is surrounded by the subsequently applied organic optoelectronic stack before the rear contact is applied. Before the rear contact is applied, a structuring is carried out, preferably as laser structuring, in order that the integrated bypass diode can be connected in parallel with the optoelectronic cell(s).

FIG. 12 shows the current-voltage profile of a further embodiment of a component for integration as an integrated bypass diode in a sandwich arrangement. This concerns a single-carrier device comprising hole-conducting materials for two different thicknesses of the i-HTL layer (and identical p-HTL materials p-HTL1 and p-HTL3). On an ITO-coated glass substrate, using the vacuum vapor deposition method, firstly a 40 nm thick p-HTL1 layer BF-DPB doped with 7% by weight of the dopant NDP9 was applied, followed by an intrinsic layer (i-HTL2) composed of 4P-TPD. The thickness of this layer was varied from 20 nm to 60 nm. A further 40 nm thick BF-DPB layer, doped with 7% by weight of NDP9, was subsequently applied. 100 nm Al was deposited as top contact. All layers were deposited by means of shadow masks. On account of the barrier of HLT1 and HLT3 with respect to HTL2, only little current flows at low voltages (+1 V). At higher voltages, said barrier can be overcome more easily and the current flow rises exponentially with the voltage. The blocking-state region can be set by way of the height of the barrier and the thickness of the intrinsic layer.

Despite identical materials HTL1 and HTL3 the current-voltage profile is not entirely symmetrical, which is presumably attributable to an influence on the adjoining different electrodes (ITO/p-HTL1/i-HTL2/p-HTL3/Al). This component is also suitable for integration as a bypass diode in a sandwich arrangement.

It is expedient to additionally introduce further intermediate layers into the stack of the organic optoelectronic layer or between the organic stack and the electrodes. For example applying an electrically conductive layer after applying the integrated bypass diode.

### Examples of Laser-Structured Arrangement

In this exemplary embodiment of the laser-structured arrangement, the integrated bypass diode comprises the same stack as the stack of the optoelectronic cells.

The stack of the optoelectronic cells and of the integrated bypass diode is applied by means of vapor deposition in vacuo in the same production process. The structuring according to the invention, preferably as laser structuring, during the production process results in the separation into optoelectronic cells and integrated bypass diodes.

The advantage is that this arrangement can be produced in one run during a roll-to-roll method.

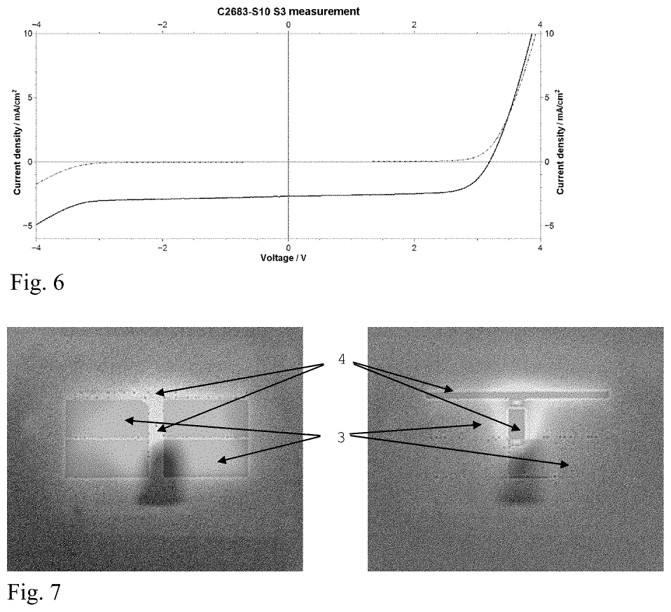

FIG. 4 shows an arrangement comprising two cell strips having optoelectronic cells (3), which are interrupted in the center by a strip having integrated bypass diodes (4). In this embodiment arrangement, the bypass diode assigned to the upper cell strip of the optoelectronic cells is situated above said cell strip. The bypass diode assigned to the second cell strip is integrated into the preceding cell strip. The structuring markings are clearly discernible. FIG. 7 shows two thermal image recordings, on the left during “operation of the optoelectronic cells” and on the right during operation of the bypass diode. FIG. 6 illustrates the current-voltage diagram under illumination “solid line” and under complete shading (without illumination) “dashed line”. In contrast to a module without a bypass diode, the current-voltage characteristic curve for voltages of less than −3 V exhibits a current flow that increases in terms of magnitude as the voltage decreases. Here according to the invention the current flows through the bypass diode and the optoelectronic cells of the module are not loaded.

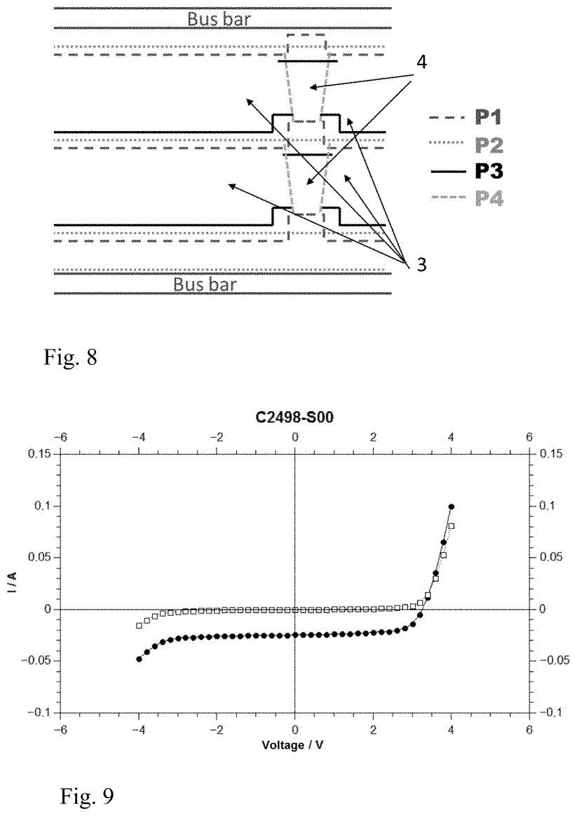

In a further exemplary embodiment for the laser-structured embodiment, the integrated bypass diodes are integrated alongside the two adjoining corresponding cell strips. FIG. 9 shows an embodiment in which an arrangement of the integrated bypass diode alongside the corresponding cell strip was realized by the additional use of P4 laser cuts. The advantage of this example over the first exemplary embodiment of the laser-integrated bypass diode is that the upper strip of the “first” integrated bypass diode can be reduced and it is thereby possible to enlarge the usable region for obtaining current. Production can be carried out both by means of laser processing and by means of shadow masks. The example and the current-voltage diagram are shown in FIG. 8 and FIG. 9.

In FIG. 8 this is realized by means of an additional P2 and P3 cut. The current flow is identified by the arrows. In this example, the photogenerated current flows in particular via the top contact of the shaded optoelectronic cell to the bypass diode, where it can flow via the additional P2 structuring into the bottom contact of the bypass diode to an improved extent. This leads to a reduction of the series resistance of the bypass diode and an areal homogenization of the current densities in the bypass diode.

A further embodiment with offset current flow behavior is shown in FIG. 5. The necessary structurings P1 (dashed)/P2 (dotted)/P3 (solid) are shown. In this illustration, the first integrated bypass diode is not arranged parallel to the first cell strip, that is to say that the integrated bypass diodes are arranged offset with respect to the cell strips.

Displacing the structurings makes possible an arrangement of the first integrated bypass diode also directly predominantly parallel to the first cell strip, analogously for following bypass diodes and cell strips.

The current flow into the bypass diode and out of the bypass diode (reduction of the series resistance of the bypass diode) can be improved by further structuring measures (P1, P2, P3).

While the invention has been illustrated and described in detail in the drawings and foregoing description, such illustration and description are to be considered illustrative or exemplary and not restrictive. It will be understood that changes and modifications may be made by those of ordinary skill within the scope of the following claims. In particular, the present invention covers further embodiments with any combination of features from different embodiments described above and below. Additionally, statements made herein characterizing the invention refer to an embodiment of the invention and not necessarily all embodiments.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### LIST OF REFERENCE SIGNS

0 Solar cell with integrated bypass diode
1 Bottom electrode
2 Top electrode
3 Organic stack of the optoelectronic cells/optoelectronic layer stack
4 Integrated bypass diode without contacts
5 Integrated bypass diode without contacts
6 Photoactive layer of the optoelectronic cells
7 Transport layers
8 i-layer
9 p-layer
10 n-layer
11 Recombination zone
12 Passivation layer
13 Injection layer
14 Substrate
P1, P2, P2′, P3, P4 Structuring (laser structuring)

1: An organic component for converting light into electrical energy, comprising at least one module, at least one bottom contact in proximity to a substrate, and at least one top contact, wherein each module comprises at least two organic optoelectronic cells and at least one integrated bypass diode, wherein
a. the optoelectronic cells comprises an organic optoelectronic stacked layer system arranged between the bottom contact and the top contact, and the optoelectronic cells are connected in series,
b. the integrated bypass diode is arranged with the optoelectronic cells on a substrate such that each bypass diode is interconnected in parallel with exactly one or with a plurality of optoelectronic cells, and the integrated bypass diode without contacts is arranged such that it has the same reverse direction between the bottom contact and the top contact as strips of the optoelectronic cells, and the bypass diode is integrated in such a way by structuring, alongside the strips of the optoelectronic cells on the substrate, and
c. characterized in that the bottom contact of a strip of the optoelectronic cells is electronically connected to the top contact of an assigned bypass diode and the bottom contact of the assigned bypass diode is electronically connected to the bottom contact of an adjacent strip of optoelectronic cells.

2: An organic component for converting light into electrical energy, comprising at least one module, at least one bottom contact in proximity to a substrate, and at least one top contact, wherein each module comprises at least two organic optoelectronic cells and at least one integrated bypass diode, wherein
a. the optoelectronic cells comprises an organic optoelectronic layer system arranged between the bottom contact and a rear contact, and the optoelectronic cells are connected in series,
b. the integrated bypass diode is arranged with the optoelectronic cells on a substrate such that each bypass diode is interconnected in parallel with exactly one or with a plurality of optoelectronic cells, and the integrated bypass diode has a reverse direction between the contacts that is opposite to that of the optoelectronic cells, and the bypass diode is integrated in such a way by structuring, alongside the strips of the optoelectronic cells on the substrate, and
c. characterized in that the top contact of the bypass diode is electrically connected to the top contact of the assigned strip of optoelectronic cells and the bottom contact of the bypass diode is electrically connected to the bottom contact of the assigned strip of the optoelectronic cells.

3: An organic component for converting light into electrical energy, comprising at least one module, at least one bottom contact in proximity to a substrate, and at least one top contact, wherein each module comprises at least two organic optoelectronic cells and at least one integrated bypass diode, wherein
a. the optoelectronic cells comprises an organic optoelectronic layer system arranged between the bottom contact and a rear contact, and the optoelectronic cells are connected in series,
b. the integrated bypass diodes are arranged with the optoelectronic cells on a substrate such that each bypass diode is interconnected in parallel with exactly one or with a plurality of optoelectronic cells, wherein
c. the integrated bypass diodes without contacts and the optoelectronic layer stack are arranged in a manner stacked one above another between a common bottom contact and a common top contact, wherein
i) the layer sequence of the integrated bypass diode without contacts is applied on the bottom contact,
ii) the optoelectronic layer stack is applied between the bottom contact and the top contact or is applied between the bypass diodes without contacts, applied on the bottom contact, and the top contact, and
iii) the region of the bypass diode and the optoelectronic layer stack is interrupted by a structuring process such that the layer system of the integrated bypass diode without contacts is electrically connected to the top contact.

4: The organic component as claimed in claim 3, characterized in that the integrated bypass diode is a single-carrier device.

5: The organic component as claimed in claim 1, wherein the bottom contact forms a cathode and the top contact forms an anode, wherein the top contact comprises a metal having a thermal work function of less than 4.5 eV and the integrated bypass diode comprises at least one of the following layers or layer sequences:
a. an inorganic or organic doped layer, wherein the concentration of the dopants in the layer is less than 10%, or
b. an organic or non-organic, non-intrinsic layer having a work function of greater than 4.5 eV, followed by an insulating layer for forming a tunnel diode with respect to the electrode, or
c. a layer comprising a highly doped organic p-type conductor.

6: The organic component as claimed in claim 1, wherein the bottom contact forms a cathode and the top contact forms an anode, wherein the top contact comprises a metal or a material having an arbitrary thermal work function or wherein a layer comprising a degenerate or highly doped n-type conductor having a thermal work function of less than approximately 4.5 eV is arranged in the region of the integrated bypass diode below the top contact and the bypass diode comprises at least one of the following layers or layer sequences:
a. an inorganic or organic layer, wherein the layer is applied on the bottom contact, or
b. a non-intrinsic layer having a work function of greater than 4.5 eV followed by an insulating layer for forming a tunnel diode with respect to the degenerate or highly doped n-type conductor layer.

7: The organic component as claimed in claim 1, characterized in that the thermal work function of the cathode is increased by:
a. intermediate layers, comprising molybdenum oxide, tungsten oxide, PEDOT:PSS or self-assembled monolayers, or a combination of these materials, and/or
b. by pretreating the electrode to a value of greater than 4.5 eV.

8: The organic component as claimed in claim 1, wherein the inorganic or organic hole-conducting layer of the integrated bypass diode comprises at least one of the following materials or material classes:
a. low molecular weight, hole-conducting substance with conjugated pi electron system and optionally conjugated or non-conjugated side chains;
b. substances which have correspondingly functionalized side groups or contain a second material which can react with the actual hole-conducting substance by way of correspondingly functionalized side groups;
c. polymeric hole-conducting substances, and/or compounds having suitable non-conjugated side chains which ensure a sufficient solubility for a printing process;
d. a mixture of a polymeric, conjugated or non-conjugated substance and a low molecular weight, hole-conducting substance.

9: The organic component as claimed in claim 1, wherein the bypass diode contains an inorganic electron-conducting layer or an organic, electron-conducting layer comprising at least one of the following materials or material classes:
a. low molecular weight, electron-conducting substance,
b. preferably compounds having a moderate electron affinity of between approximately 3.5 eV and approximately 4.5 eV, and compounds having suitable non-conjugated side chains which ensure a sufficient solubility for a printing process,
c. a compound selected from bay-linked dimers, trimers and oligomers of perylenebisimide or decacyclenetriimides having the solubility-mediating groups mentioned,
d. a compound selected from boron subphthalocyanines, phthalocyanines, polycyclic aromatic and heteroaromatic hydrocarbons having electron-withdrawing substituents (F, Cl, CN), which likewise carry solubility-mediating alkyl, alkoxy, oligoether and partly fluorinated alkyl groups, furthermore fluoranthene-fused imides having solubility-mediating groups, or tetraazabenzodifluoranthenediimides and diketopyrrolopyrrole (DPP)-functionalized acceptors having the abovementioned solubility-mediating groups;
e. 9,9′-bifluorenylidenes;
f. truxenone derivatives and dicyanovinylenes and cyanocarboxyvinylenes derived therefrom,
g. calamitically shaped molecules having an electron-rich central group,
h. polymeric electron-conducting substances and compounds having suitable non-conjugated side chains which ensure a sufficient solubility for a printing process,
i. mixture of a polymeric, conjugated or non-conjugated substance and a low molecular weight electron-conducting substance; and compounds having suitable non-conjugated side chains which ensure a sufficient solubility for a printing process.

10: The organic component as claimed in claim 1, wherein the bypass diode contains an organic, bipolar conductive layer comprising a mixture of an electron-conducting and a hole-conducting material.

11: The organic component as claimed in claim 1, wherein the bottom contact of the optoelectronic cells and of the integrated bypass diode forms a cathode and the top contact forms an anode,
a. wherein the top contact, at least in the region of the bypass diode, comprises a metal having a high thermal work function of greater than 4.8 eV, or a metal or a metal alloy having an arbitrary thermal work function in combination with a layer of a semiconducting oxide having a high thermal work function of greater than approximately 5 eV, and/or
b. the bottom contact, at least in the region of the integrated bypass diode, comprises a conductive oxide or a metal having a low thermal work function of less than approximately 4.5 eV,
c. the bypass diode comprises at least one of the following layers or layer sequences:
i) undoped or very slightly n-doped semiconducting oxide having a thermal work function of less than approximately 4.5 eV,
ii) an undoped or very slightly n-doped electron-conducting substance,
iii) an undoped or very slightly p-doped hole-conducting substance, or
iv) a mixed layer of an electron-conducting and a hole-conducting substances.

12: The organic component as claimed in claim 1, wherein the layer stack, in the region of the bypass diode, additionally comprises one or a plurality of doped layers having a high thermal work function, of greater than approximately 4.8 eV on the part of the anode and/or doped layers having a low thermal work function, of less than approximately 4.5 eV, on the part of the cathode.

13: The organic component as claimed in claim 1, wherein the optoelectronic cells and the bypass diodes comprise the same stack of semiconductor materials.

14: The organic component as claimed in claim 1, wherein the photovoltaic effect of the layer stack in the region of the bypass diode is reduced by pulsed lasers or by bombardment with charged particles.

15: The organic component as claimed in claim 1, characterized in that additional structurings for reducing the series resistance are inserted.

16: The organic component as claimed in claim 1, characterized in that the integrated bypass diode comprises electron-conducting and/or hole-conducting material.

17: The organic component as claimed in claim 1, wherein the strips of the optoelectronic cells, i.e. the optoelectronic layer stack, are solar cells or photodetectors.

18: The organic component as claimed in claim 1, characterized in that the bypass diodes are in the form of discrete shapes.

19: The organic component as claimed in claim 1, characterized in that
a. the sum of the area proportion of all arranged bypass diodes on the bottom contact is less than 20% of the bottom contact area, or
b. the sum of the areas of all arranged bypass diodes of a module is less than 20% of the area of the module.

20: A method for producing organic solar cells with integrated bypass diodes, comprising the following steps:
a. providing a substrate,
b. applying a bottom electrode and structuring the bottom electrode,
c. applying a layer stack of the integrated bypass diode and a layer stack of the optoelectronic cells without their rear contacts with structuring, after applying individual or a plurality of layers of the bypass diode and/or the layer stack of the optoelectronic cells; and
d. applying the rear contact including its structuring.

21: The method as claimed in claim 20, characterized in that the optoelectronic cells are connected in series and are arranged between bottom and rear contacts, and the integrated bypass diode without its rear contact is applied before depositing the cells of the optoelectronic layer system, i.e. before applying the optoelectronic layer stack, and the integrated bypass diode is electrically connected to the top contact by a suitable structuring of the subsequently applied optoelectronic layer system.

22: The method as claimed in claim 20, characterized in that applying the layer sequences of the bypass diodes on a region of the bottom contact is carried out by a printing process or by vapor deposition of the materials to be applied.

23: The method as claimed in claim 20, characterized in that the structuring of the optoelectronic layer system on the region of the respective bypass diode is carried out by using shadow masks, structured printing methods or laser ablation.

24: The method as claimed in claim 20, characterized in that the integrated bypass diode or the integrated bypass diodes without the rear contact thereof are applied before depositing the optoelectronic layers of the cell of the optoelectronic component on the bottom contact of the respective optoelectronic cell and are electrically connected to the rear contact of the respective optoelectronic cell a suitable structuring of the subsequently applied optoelectronic layer system.

25: The method as claimed in claim 20, characterized in that applying the integrated bypass diode or the integrated bypass diodes is carried out at the same time as depositing the optoelectronic layers of the cell of the optoelectronic component on the bottom contact of the respective optoelectronic cell and the bypass diode and the optoelectronic cells are electrically connected to the rear contact thereof by means of a suitable structuring.

26: The method as claimed in claim 20, wherein the structuring of the optoelectronic cells and/or of the bypass diode is carried out during the process of applying the layer sequences and/or after applying all layer sequences of the optoelectronic cells and/or the bypass diode.

27: The method as claimed in claim 20, wherein additional structurings are inserted between the optoelectronic layers and the integrated bypass diode in the case of arrangement alongside one another between the two electrodes in order to reduce the series resistance of the integrated bypass diode.

28: The method as claimed in claim 20, wherein the photoactive layer of at least one subcell in the region of the integrated bypass diode in the case of arrangement of the integrated bypass diode alongside the optoelectronic layers between the two electrodes and the integrated bypass diode has a stack almost identical to the optoelectronic layers, is treated by means of pulsed laser radiation, UV radiation or bombardment with charged particles.

29: An organic optoelectronic component, comprising modules or cells comprising an integrated bypass diode produced by the method of claim 20.
